(19) United States
(12) Patent Application Publication
(10) Pub. No.: US 2022/0208559 A1
(43) Pub. Date: Jun. 30, 2022

(54) METHOD AND APPARATUS FOR CHIP MANUFACTURING

(71) Applicant: ADVANCED MICRO DEVICES, INC., Santa Clara, CA (US)

(72) Inventors: Ai-Tee Ang, Hsinchu (TW); I-Tseng Lee, Kaohsiung (TW)

(21) Appl. No.: 17/137,562

(22) Filed: Dec. 30, 2020

(51) Int. Cl. H01L 21/56; H01L 23/31; H01L 21/67; H01L 25/07

(52) U.S. Cl. CPC H01L 21/565; H01L 23/3157; H01L 25/072; H01L 21/67126; H01L 21/561; H01L 21/67121

(57) ABSTRACT

Chip manufacturing, including: assembling at least two chips on a layer; and applying mold compound on the at least two chips to the sides and bottom including flowing around interconnects, thereby leaving the top of each of the at least two chips exposed.

### BACKGROUND

In order to improve the speed, functionality, and efficiency of semiconductor chips, traditional manufacturing is no longer sufficient. Innovation is required in manufacturing.

### BRIEF DESCRIPTION OF THE DRAWINGS

FIG. 1 is a block diagram of a typical semiconductor chip package.

FIG. 2 is a flowchart of a method for manufacturing a typical semiconductor chip package.

FIG. 3A is a block diagram of an example semiconductor chip package according to some embodiments.

FIG. 3B is a block diagram of another example semiconductor chip package according to some embodiments.

FIG. 4 is a flow chart illustrating an exemplary method for manufacturing an example semiconductor chip package according to some embodiments.

FIG. 5 is a flow chart illustrating an exemplary method for manufacturing an example semiconductor chip package according to some embodiments.

FIG. 6 is a flow chart illustrating an exemplary method for manufacturing an example semiconductor chip package according to some embodiments.

### DETAILED DESCRIPTION

In some embodiments, a method of efficient chip manufacturing includes: assembling at least two chips on a layer; and applying mold compound on the at least two chips to the sides and bottom including flowing around interconnects, thereby leaving the top of each of the at least two chips exposed.

In some embodiments, method of efficient chip manufacturing further includes attaching a substrate. In some embodiments, the at least two chips are heterogenous chips. In some embodiments, the at least two chips are chips of the same type. In some embodiments, the at least two chips are a two dimensional (2.5d) package. In some embodiments, the at least two chips are a die-last wafer-level fanout package. In some embodiments, the at least two chips are a die-first wafer-level fanout package.

In some embodiments, an apparatus with efficient chip manufacturing formed by steps including: assembling at least two chips on an interposer; and applying mold compound on the at least two chips to the sides and bottom including flowing around interconnects, thereby leaving the top of each of the at least two chips exposed.

In some embodiments, the apparatus with efficient chip manufacturing formed by steps includes attaching a substrate. In some embodiments, the at least two chips are heterogenous chips. In some embodiments, the at least two chips are chips of the same type. In some embodiments, the apparatus is a two dimensional (2.5d) package. In some embodiments, the apparatus is a die-last wafer-level fanout package. In some embodiments, the apparatus is a die-first wafer-level fanout package.

In some embodiments, an apparatus with efficient chip manufacturing formed by steps including: assembling at least two chips on a redistribution layer; and applying mold compound on the at least two chips to the sides and bottom including flowing around interconnects, thereby leaving the top of each of the at least two chips exposed.

In some embodiments, the apparatus with efficient chip manufacturing formed by steps includes attaching a substrate. In some embodiments, the at least two chips are heterogenous chips. In some embodiments, the apparatus is a two dimensional (2.5d) package. In some embodiments, the at least two chips are on an embedded silicon bridge fan-out. In some embodiments, the apparatus is a die-last wafer-level fanout package. In some embodiments, the apparatus is a die-first wafer-level fanout package.

In modern semiconductor chips, in order to improve upon the speed and capability of microchips, chips or modular chiplets are stacked in a package. In a three-dimensional (3D) chip, several chiplets are stacked vertically on an interposer. In a two-dimensional (2.5D) chip, the chiplets are stacked in a single layer on an interposer. In some semiconductor chips, the chiplets are stacked in a single layer or several layers on a silicon bridge instead of an interposer. In some semiconductor chips, the chiplets are stacked in a single layer on a substrate without an interposer.

In fan-out packaging, chiplets are packaged on a redistribution layer with or without an interposer. In some semiconductor chips, the chiplets are stacked in a single layer on an embedded silicon bridge fan-out. In wafer level packaging, the dies are packaged while still on the wafer, rather than conventional packaging where the finished wafer is diced or singulated into individual chips then encapsulated. In die-first fan-out wafer level packaging, the dies are singulated then placed face-down or face-up on a temporary carrier and secured by underfill and encapsulated by molding. The die-first fan-out wafer level packaging then includes forming a reconstituted carrier, and building the redistribution layer, releasing from the temporary carrier, and dicing the reconstituted carrier into individual packages. In die-last fan-out wafer level packaging, the redistribution layer is built on a wafer, then the dies are singulated and assembled on the redistribution layer and secured by underfill then encapsulated by molding, the temporary carrier is released, and the reconstituted wafer is diced into individual packages.

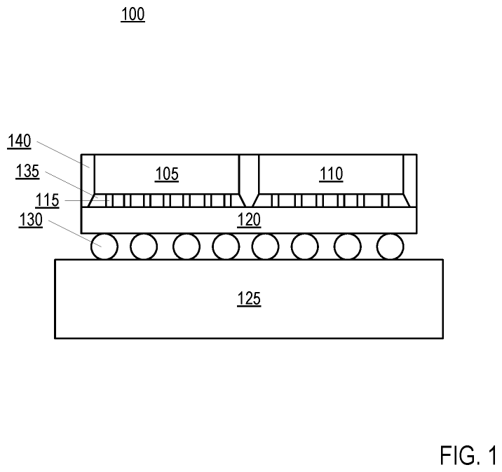

FIG. 1 is a block diagram of a typical semiconductor chip package 100. The typical semiconductor chip package 100 includes several chips. In some embodiments, chips 105 and 110 are the same type and in some embodiments, chips 105 and 110 and heterogeneous. In some embodiments, chips 105 and 110 include systems on a chip (SOC), memory, graphics processors, and other chips including specialized processing or communication chips. In some embodiments, chips 105 and 110 can have different pitch, size, material, process nodes, etc. In some embodiments, there can be more chips including multiple processor chips, multiple memory chips, and multiple other chips. The typical semiconductor chip package 100 includes microbumps 115 that connect to redistribution layer 120. While only redistribution layer 120 is shown, in some embodiments, redistribution layer is atop an interposer (not shown). Alternatively, in some embodiments, chips 105 and 110 can attach directly to the interposer. Redistribution layer 120 is connected to substrate 125 by bumps 130. In some embodiments, bumps 130 can be a ball grid array (BGA) or controlled collapse chip connection (C4) bumps. In typical semiconductor chip package 100, the microbumps 115 are surrounded and secured by underfill 135. The underfill 135 can be a resin or epoxy. The entire typical semiconductor chip package 110 is secured by mold compound 140. The mold compound 140 can be epoxy. In some embodiments, typical semiconductor chip package 100 includes additional structures including copper pillars, ring, lid, etc.

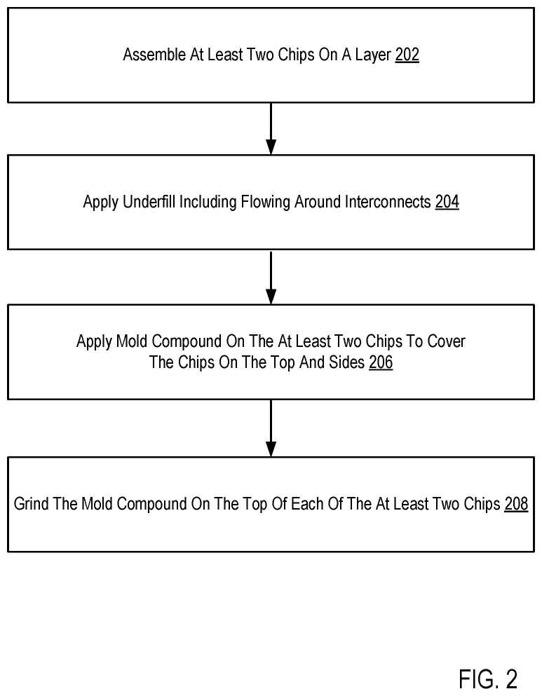

For further explanation, FIG. 2 sets forth a flow chart illustrating an exemplary method for manufacturing a typical semiconductor chip package. While the steps are shown in manufacturing a typical semiconductor chip package, not all steps are shown and, in some embodiments, additional steps can be added. The method of FIG. 2 includes assembling 202 at least two chips onto a layer. The chips 105 and 110 have been prepared with microbumps 115.

The method of FIG. 2 also includes applying 204 underfill including flowing around interconnects. Applying 204 underfill 135 includes applying a resin or epoxy that flows. In some embodiments, the underfill 135 works to stabilize interconnects or microbumps 115 and secure the positioning of chips 105 and 110. In some embodiments, the underfill 135 is an epoxy material.

The method of FIG. 2 also includes applying 206 a mold compound on the at least two chips to cover the chips on the top and sides. Applying 206 a mold compound includes depositing a mold compound 140 on the entire top and sides of the chips 105 and 110. In some embodiments, the mold compound 140 is an epoxy material.

The method of FIG. 2 also includes grinding 208 the mold compound on the top of each of the at least two chips. Grinding 208 the mold compound 140 includes grinding the mold compound 140 to expose the back side of the chips 105 and 110.

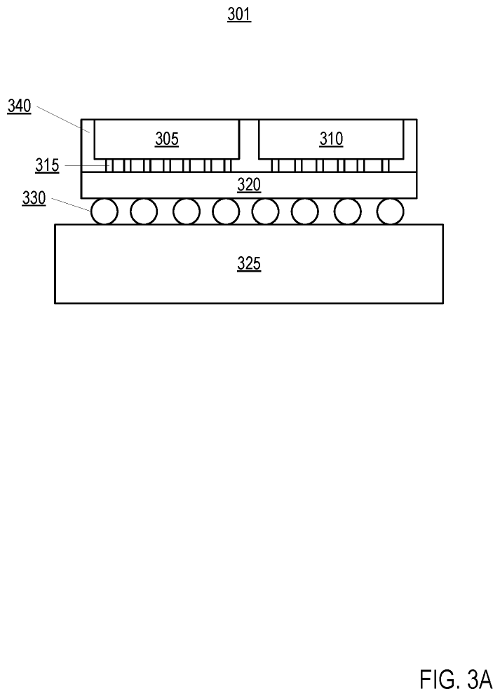

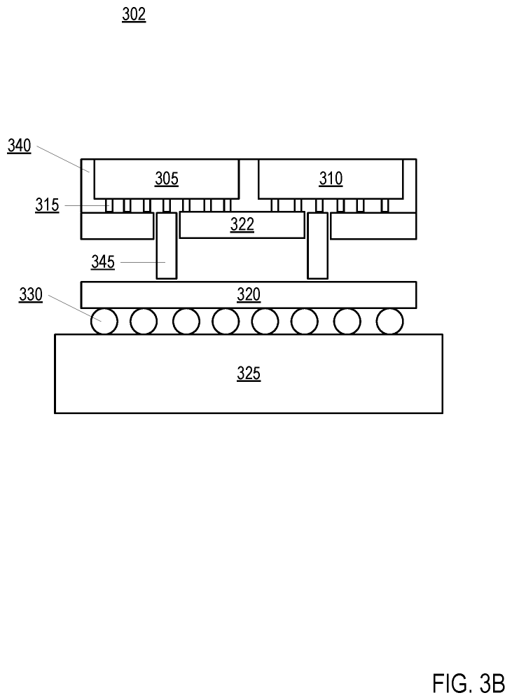

FIG. 3A is a block diagram of an example semiconductor chip package 301 according to some embodiments. Similar to the typical semiconductor chip package 100 of FIG. 1, the example semiconductor chip package 301 includes several chips. In some embodiments, chips 305 and 310 are the same type and in some embodiments, chips 305 and 310 and heterogeneous. In some embodiments, chips 305 and 310 include systems on a chip (SOC), memory, graphics processors, and other chips including specialized processing or communication chips. In some embodiments, chips 305 and 310 can have different pitch, size, material, process nodes, etc. In some embodiments, there can be more chips including multiple processor chips, multiple memory chips, and multiple other chips. Similar to the typical semiconductor chip package 100 of FIG. 1, the example semiconductor chip package 301 includes microbumps 315 that connect to redistribution layer 320. Similar to the typical semiconductor chip package 100 of FIG. 1, the redistribution layer 320 is connected to substrate 325 by bumps 330. In some embodiments, bumps 330 can be a ball grid array (BGA) or controlled collapse chip connection (C4) bumps.

In example semiconductor chip package 301, the chips 305 and 310 and the microbumps 315 are surrounded and secured by mold compound 340. The mold compound 340 can be epoxy. In some embodiments, typical semiconductor chip package 301 includes additional structures including copper pillars, ring, lid, etc.

FIG. 3B is a block diagram of another example semiconductor chip package 302 according to some embodiments. Similar to the example semiconductor chip package 301 of FIG. 3A, the example semiconductor chip package 302 includes several chips. In some embodiments, chips 305 and 310 are the same type and in some embodiments, chips 305 and 310 and heterogeneous. In some embodiments, chips 305 and 310 include systems on a chip (SOC), memory, graphics processors, and other chips including specialized processing or communication chips. In some embodiments, chips 305 and 310 can have different pitch, size, material, process nodes, etc. In some embodiments, there can be more chips including multiple processor chips, multiple memory chips, and multiple other chips. The example semiconductor chip package 302 includes microbumps 315 that connect to interposer 322. Interposer 322 connects chips 305 and 310 vertically by copper pillars 345 through the through silicon vias (TSV). Interposer 322 can also connect chips 305 and 310 horizontally through a redistribution layer atop the interposer 322. Similar to the typical semiconductor chip package 301 of FIG. 3A, the redistribution layer 320 is connected to substrate 325 by bumps 330. In some embodiments, bumps 330 can be a ball grid array (BGA) or controlled collapse chip connection (C4) bumps.

In example semiconductor chip package 302, similar to the typical semiconductor chip package 301 of FIG. 3A, the chips 305 and 310 and the microbumps 315 are surrounded and secured by mold compound 340. The mold compound 340 can be epoxy. In some embodiments, typical semiconductor chip package 302 includes additional structures including copper pillars, ring, lid, etc.

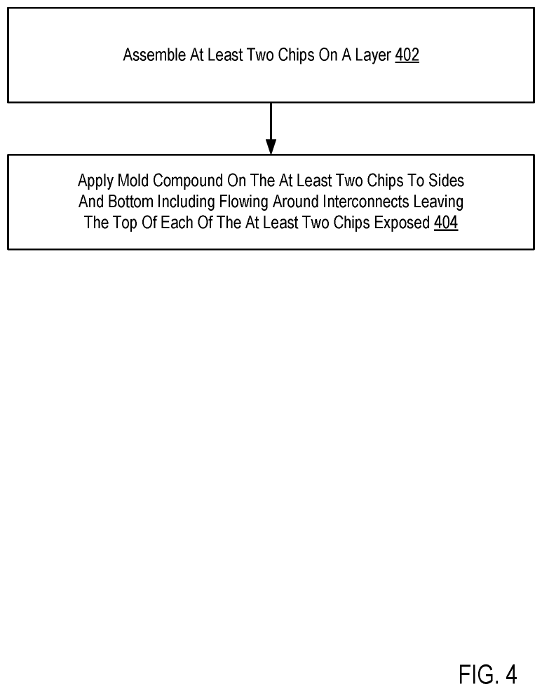

For further explanation, FIG. 4 sets forth a flow chart illustrating an exemplary method for manufacturing an example semiconductor chip package according to some embodiments. While the steps are shown in manufacturing a typical semiconductor chip package, not all steps are shown and, in some embodiments, additional steps can be added. Similar to the method of FIG. 2, the method of FIG. 4 includes assembling 402 at least two chips onto a layer. The chips 305 and 310 have been prepared with microbumps 315.

The method of FIG. 4 also includes applying 404 mold compound on the at least two chips to the sides and bottom including flowing around interconnects. Applying 404 a mold compound includes depositing a mold compound 340 on the sides and bottom of the chips 305 and 310 including flowing around the interconnects or microbumps 315. In some embodiments, the mold compound 340 is an epoxy material. The tops of each of the at least two chips are left exposed.

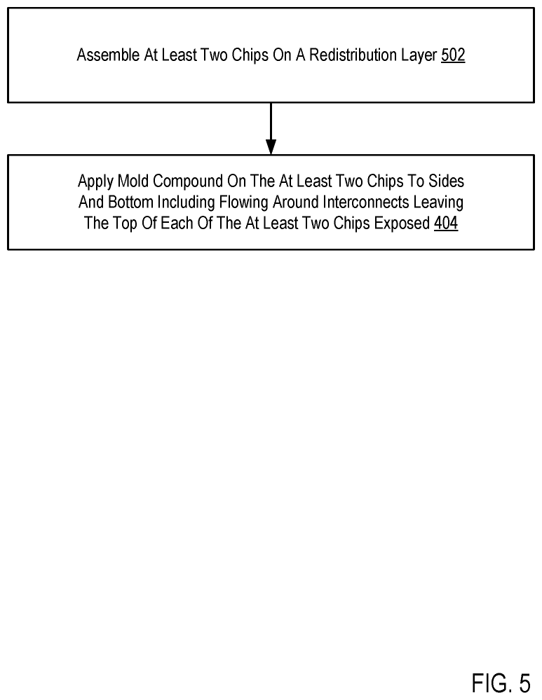

For further explanation, FIG. 5 sets forth a flow chart illustrating an exemplary method for manufacturing an example semiconductor chip package that includes applying 404 a mold compound includes depositing a mold compound 340 on the sides and bottom of the chips 305 and 310 including flowing around the interconnects or microbumps 315. The tops of each of the at least two chips are left exposed.

The method of FIG. 5 differs from FIG. 4 in that the method includes assembling 502 the at least two chips on a redistribution layer.

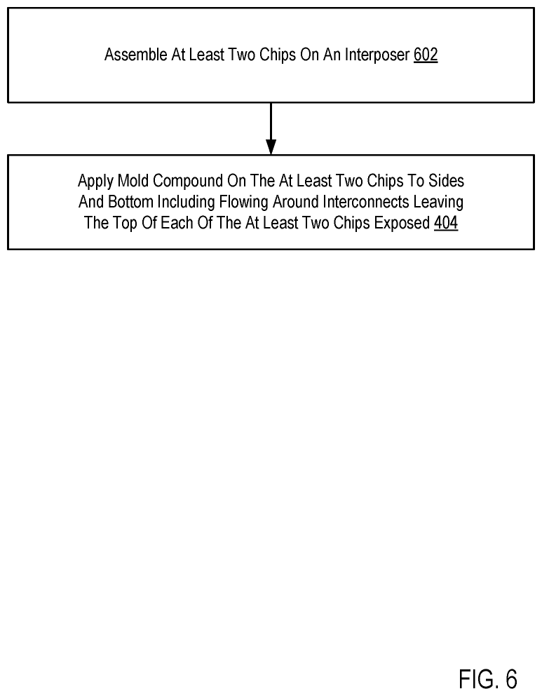

For further explanation, FIG. 6 sets forth a flow chart illustrating an exemplary method for manufacturing an example semiconductor chip package that includes applying 404 a mold compound includes depositing a mold compound 340 on the sides and bottom of the chips 305 and 310 including flowing around the interconnects or microbumps 315. The tops of each of the at least two chips are left exposed.

The method of FIG. 6 differs from FIG. 4 in that the method includes assembling 602 the at least two chips on an interposer.

In view of the explanations set forth above, readers will recognize that the benefits of efficient manufacturing of a semiconductor chip package include:
Reduced steps in the process of manufacturing of a semiconductor chip package reducing stress of the semiconductor chip package by reducing the stress of grinding.
Using one material in manufacturing a semiconductor chip package instead of two improves strength and reduces areas of contact failure.

By applying a mold compound to perform as a combined mold compound and underfill, the semiconductor chip package has improved strength, reduced cycle time, and reduced costs. By reducing grinding, the semiconductor chip package is manufactured with less stress.

The semiconductor chip package with efficient manufacturing can be used in in general datacenters or in specific purpose devices.

It will be understood from the foregoing description that modifications and changes can be made in various embodiments of the present disclosure. The descriptions in this specification are for purposes of illustration only and are not to be construed in a limiting sense. The scope of the present disclosure is limited only by the language of the following claims.

1. A method of efficient chip manufacturing, the method comprising:
assembling at least two chips on a layer; and
applying mold compound to the sides and bottom of the chips including flowing around interconnects, thereby leaving the top of each of the at least two chips exposed.

2. The method of claim 1, further comprising:
attaching a substrate.

3. The method of claim 1, wherein the at least two chips are heterogenous chips.

4. The method of claim 1, wherein the at least two chips are chips of the same type.

5. The method of claim 1, wherein the at least two chips are a two dimensional (2.5d) package.

6. The method of claim 1, wherein the at least two chips are a die-last wafer-level fanout package.

7. The method of claim 1, wherein the at least two chips are a die-first wafer-level fanout package.

8. An apparatus comprising:
at least two chips assembled on one of a redistribution layer and an interposer; and
mold compound applied to the sides and bottom of the chips including flowing around interconnects, thereby leaving the top of each of the at least two chips exposed.

9. The apparatus of claim 8, further comprising:
a substrate attached to the chips.

10. The apparatus of claim 8, wherein the at least two chips are heterogenous chips.

11. The apparatus of claim 8, wherein the apparatus is a two dimensional (2.5d) package.

12. The apparatus of claim 8, wherein the apparatus is a die-last wafer-level fanout package.

13. The apparatus of claim 8, wherein the apparatus is a die-first wafer-level fanout package.

14. An apparatus formed by steps comprising:
assembling at least two chips on one of a redistribution layer and an interposer; and
applying mold compound to the sides and bottom of the chips including flowing around interconnects, thereby leaving the top of each of the at least two chips exposed.

15. The apparatus of claim 15, formed by further steps comprising:
attaching a substrate.

16. The apparatus of claim 15, wherein the at least two chips are heterogenous chips.

17. The apparatus of claim 15, wherein the apparatus is a two dimensional (2.5d) package.

18. The apparatus of claim 15, wherein the at least two chips are on an embedded silicon bridge fan-out.

19. The apparatus of claim 15, wherein the apparatus is a die-last wafer-level fanout package.

20. The apparatus of claim 15, wherein the apparatus is a die-first wafer-level fanout package.
